(19) United States
(12) Patent Application Publication
(10) Pub. No.: US 2007/0295394 A1
(43) Pub. Date: Dec. 27, 2007

(54) Method for building thin film flexible solar cells on bio-based plastic substrates

(75) Inventor: David Donghie Lee, Agua Dulce, CA (US)

Correspondence Address: EDWIN TARVER, 16830 Ventura Blvd., SUITE 360, Encino, CA, 91436, US

(73) Assignee: BioSolar, Inc.

(21) Appl. No.: 11/476,518

(22) Filed: Jun. 27, 2006

(51) Int. Cl. H01L 31/00

(52) U.S. Cl. 136/252

(57) ABSTRACT

A process for building thin film flexible solar cells using a bio-based plastic substrate comprising the steps of; degasing the bio-based substrate at a temperature of 120 degrees Celsius, and forming a barrier layer of silicon oxide through the process of chemical vapor deposition (CVD). The silicon oxide layer seals micro-cracks in the bio-based plastic substrate and provides a stable substrate during the production and operation of the thin film PV device. The resulting substrate is used to build a thin film solar cell employing a conventional low temperature CVD chamber process by depositing the required layers of semiconductor and conductive materials.

### STATEMENT REGARDING COPYRIGHTED MATERIAL

Portions of the disclosure of this patent document contain material that is subject to copyright protection. The copyright owner has no objection to the facsimile reproduction by anyone of the patent document or the patent disclosure as it appears in the Patent and Trademark Office file or records, but otherwise reserves all copyright rights whatsoever.

### BACKGROUND

This invention relates generally to the field of renewable energy and more specifically to a process for building thin film flexible solar cells on bio-based plastic substrates.

Solar energy provides many advantages over traditional energy sources. Energy from the sun is virtually unlimited and accessible throughout the world. It requires no extraction of natural resources, and can be converted to electricity without harming to the environment. Solar energy can also be collected and stored for use when no light sources are available. Therefore, if harnessed economically, it provides an environmentally friendly source of energy without depleting natural resources. By contrast, fossil fuels are available in limited supply and both their use and extraction processes cause environmental damage. The use of fossil fuel also requires a constant supply of raw material that becomes increasingly difficult to obtain.

A variety of solar cells have been developed using different fabrication techniques to take advantage of solar energy. One type of solar cell is formed with crystalline silicon. Crystalline silicon is formed by melting silicon and drawing an ingot of crystallized silicon of a particular size. Alternatively, a ribbon of crystalline silicon can be pulled from molten silicon to form a crystalline silicon solar cell. A conductor is placed on either side of the crystalline silicon to form the solar cell.

These processes use high temperatures making solar cells expensive to manufacture. Solar cells created in this manner also have a rigid structure, making packaging difficult and expensive. The manufacturing process limits the cells' maximum size, as it is difficult to slice the resulting crystalline silicon thin enough to provide a transparent or flexible solar cell.

However, these structures are efficient relative to other types of solar cells presently available commercially. Therefore, crystalline solar cells are used primarily for applications where efficiency is more important than cost and where flexibility is not needed; for instance on satellite panels.

Another type of solar cell is formed with polycrystalline silicon. These may be formed as thin layers on wafers and can be made thinner than crystalline silicon solar cells. Polycrystalline silicon is formed by heating amorphous silicon which begins to crystallize above 1400° C. Because of the high temperature, this process can only use substrates with high melting points and are not appropriate for substrates made of plastics or other materials that melt at lower temperatures.

When manufacturing flat panel displays, it is known to use lasers to form polycrystalline silicon thin film transistors (“TFTs”). This method has not included the formation of P-N junctions. Moreover, these manufacturing processes generally form single transistors and are not used for large sheets of polycrystalline silicon. In addition, lasers have been used in the manufacture of solar cells, but only to mechanically form (slice, pattern, etch, etc.) the solar cells.

Doped layers of amorphous silicon have also been used to form solar cells. This solves some of the inherent problems with crystalline silicon or polycrystalline solar cells. Principally, amorphous silicon can be formed using low temperature processes. Therefore, it can be formed on plastic and other flexible substrates, and formed over large surfaces. Also, the processing techniques are less expensive.

Current research and product development mainly concern thin film PV devices in an effort to capitalize on the lower cost and diversity of applications of amorphous silicon solar cells. The thin film cell design employs less than 1.5 microns of material thickness as opposed to an approximate 400 microns of material thickness for multi-crystalline cell designs. Because of the reduction of cell thickness, and flexibility in cell structure, this type of cell is known as a “thin film” photo voltaic (PV) design.

To control costs and address environmental concerns, large volumes of thin film PV devices should be manufactured on bio-based plastic substrates rather than petroleum-based plastic substrates. Since petroleum is a depleting resource with supply dependent on a number of geo-political factors, costs can be uncertain.

Bio-based plastics are currently made by a number of manufacturers from renewable resources such as corn and potato starch. The supply and costs of these resources is far more stable than petroleum. Another problem with the use of petroleum is the damaging effects that production, distribution, and use have on the environment. Therefore there is a need for new and innovative thin film solar cells produced on bio-based plastic substrates with the intent to provide commercially viable solar cell designs that convert sun light into electrical energy.

One problem with the use of bio-based plastic substrates is that they have much lower melting and degassing temperature points than petroleum based plastic substrates. Most existing CVD chamber processes for building thin film solar cells on a conventional petroleum-based substrate are not suitable for bio-based plastic substrate due to the breakdown of bio-based substrate's physical structure at temperatures above 120 degree C. As a result, bio-based materials have not been used as substrates to make thin film solar cells.

### SUMMARY

The primary object of the present invention is to overcome the problems of degassing and deformation in bio-based substrate material during CVD chamber processing, to deposit thin layers of semiconductor materials on a bio-based substrate.

Another object of the invention is to address cost concerns, producing large volumes of thin film PV devices on a renewable resource rather than on petroleum based plastic substrates. Another object of the invention is large volume production of thin film PV devices on bio-based plastic substrates to reduce pollution associated with petroleum based plastic substrates. Other objects and advantages of the present invention will become apparent from the following detailed description, in connection with the accompanying drawings, wherein, by way of illustration and example, an embodiment of the present invention is disclosed.

In accordance with a preferred embodiment of the invention, there is disclosed a process for building thin film flexible solar cells using a bio-based plastic substrate comprising the steps of: (1) Degasing the bio-based substrate at a temperature of 120 C. which allows the bio-based material to maintain its shape without any visible bubbles or cracks and (2) forming a barrier layer of silicon oxide through the process of chemical vapor deposition (CVD) at a temperature of 120 C., thereby sealing the potential micro-cracks and providing for a stable substrate during the production and operation of the thin film PV device.

### BRIEF DESCRIPTION OF THE FIGURES

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 is a flow chart of conventional CVD operations that use a petroleum based plastic substrate.

FIG. 2 is a flow chart of the improved CVD process using a bio-based plastic substrate.

FIG. 3 is a cross sectional view of thin film solar cells based on a petroleum based substrate.

FIG. 4 is a cross sectional view of thin film solar cells manufactured using a bio-based plastic substrate.

### FIGURES—REFERENCE NUMERALS

10. Bio-Based Substrate Thin Film PV Cell and Method of Creation
11. Transparent Conductive Coating
12. Anti-reflection Coating
13. N-type “Window” Layer
14. P-type “Absorber” Layer
15. Ohmic Contact
16. Petroleum Based Substrate
17. Silicone Oxide Coating
18. Bio Based Substrate

### DETAILED DESCRIPTION

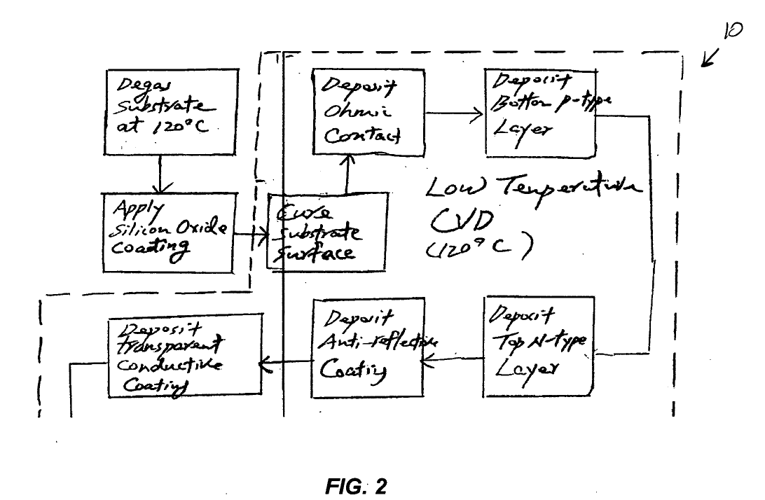

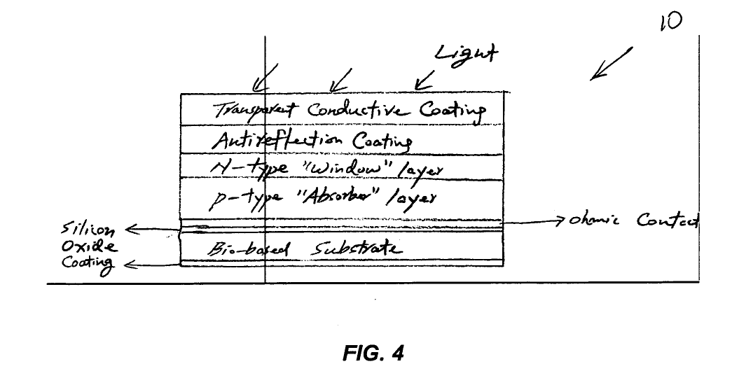

Referring to the illustrations, a preferred embodiment of a method for building thin film flexible solar cells on bio-based plastic substrates is illustrated and generally indicated as 10 in FIGS. 2 and 4. The method allows thin film flexible solar cells to be built on bio-based plastic substrates.

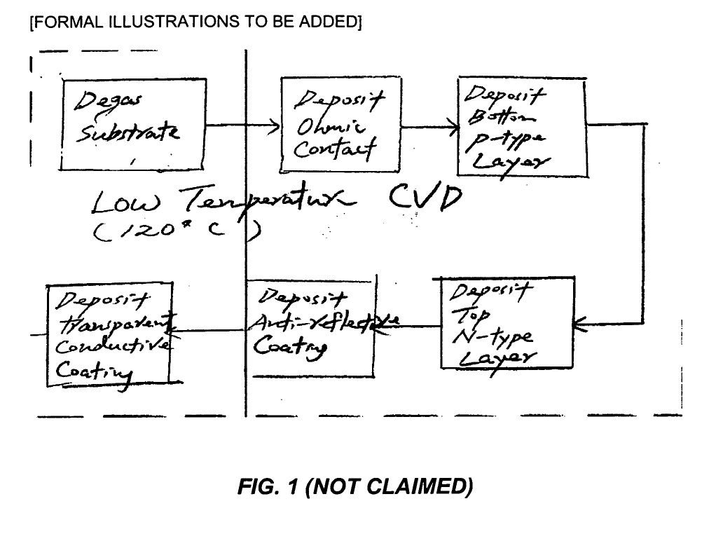

Referring to FIG. 1, the conventional process of low temperature chemical vapor deposition (CVD) is shown. In the first step, the petroleum based substrate is degassing at 150 degrees Celsius. After degassing, the ohmic contact layer is deposited. Following these processes, the P-type and N-type layers are deposited. Finally a transparent conductive coating is deposited, forming the top layer of the film.

Referring to FIG. 2, the improved process of the present invention, of low temperature CVD on a bio based plastic substrate is shown. In this improved process, the bio-based substrate is degassed at approximately 120 degrees, however after this step, a coating of silicon oxide is deposited on both sides of the substrate. The bio-based substrate is made from Poly Lactic Acid (PLA); a material generated from corn dextrose, which is fermented, then process into lactide and finally polymerized into PLA. Silicon oxide is used as the coating since it is a non-conductive material, which has been used successfully as a barrier layer in CVD processing and is compatible with PLA.

After the silicon oxide coating is applied, the substrate surface is cured to improve cross linking between the silicon oxide and the substrate. The silicon oxide reacts with oxygen to form free radicals that can cross link the silicon oxide and the bio-based substrate. The approximate curing time for this process is around ten minutes. Once the substrate is cured, the ohmic contact layer, P-type and N-type layers, anti-reflective coating and transparent coating are applied in the same manner as a typical petroleum substrate based CVD application.

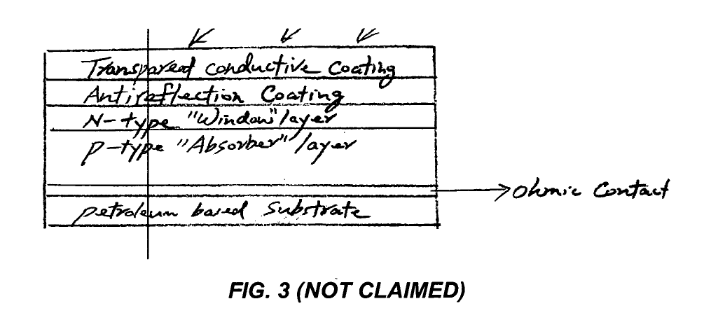

Referring to FIG. 3, a cross section of a conventional thin film solar cell is depicted. The cell consists of a petroleum based substrate on which the ohmic contact is placed. The P-type absorber layer is applied on the ohmic contact layer, and covered with the N-type window layer. Thereafter an anti-reflective coating and finally a transparent conductive coating are applied.

By contrast, referring to FIG. 4, a cross-section of the improved bio-based thin film substrate solar cell is shown. In this preferred embodiment, a bio-based substrate comprising a proprietary third party plastic is used. The bio-based plastic is coated on both sides with a silicon oxide film. The thickness of the plastic and silicon oxide coating can function at a range of between 12.7 to 254 microns, but about 50.8 microns for thin film PV applications is preferred. Once the substrate surface has cured, the same layers comprising an ohmic contact layer, a P-type absorber layer, N-type window layer, anti-reflective coating, and a transparent conductive coating are applied. The resulting solar panel has all of the advantages of a typical petroleum based substrate thin film photo voltaic, without relying on petroleum, petroleum derivatives, or other non-renewable sources for its construction.

All features disclosed in this specification, including any accompanying claims, abstract, and drawings, may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, paragraph 6. In particular, the use of “step of” in the claims herein is not intended to invoke the provisions of 35 U.S.C. §112, paragraph 6.

Although preferred embodiments of the present invention have been shown and described, various modifications and substitutions may be made thereto without departing from the spirit and scope of the invention. Accordingly, it is to be understood that the present invention has been described by way of illustration and not limitation.

What is claimed is:

1. A process for building thin film flexible solar cells using a bio-based plastic substrate comprising the steps of;
a. degasing the bio-based substrate in a chemical vapor deposition (CVD) chamber at a temperature of 120 degrees Celsius;
b. retaining the bio-based material's shape without any visible bubbles or cracks; and
c. forming a barrier layer of silicon oxide through the process of chemical vapor deposition (CVD), wherein the silicon oxide layer seals any micro-cracks in the bio-based material and provides a stable substrate during the production and operation of the thin film PV device.

2. The process of claim 1, wherein the bio-based substrate and silicon oxide coating comprises a thickness of between 12.7 to 254 microns, preferably about 50.8 microns.

3. The process of claim 2, wherein the bio-based substrate comprises a film of approximately between 25.4 and 127 microns.

4. The process of claim 3, wherein the bio-based substrate is degassed, and the chemical vapor deposition chamber operates at a temperature of approximately 120 degrees Celsius.

5. The process of claim 1, wherein the barrier layer comprises silicon oxide applied to both sides of the bio-based substrate, sealing the substrate.

6. The process of claim 5, wherein the silicon oxide barrier layer seals the bio-based film, and is examined for micro cracks and fissures with an instrument comprising a microscope or other magnifying aid.

7. The process of claim 6, wherein the thickness of the silicon oxide does not exceed 1.5 microns.

8. A thin film flexible solar cell using a bio-based plastic substrate comprising;
a. a bio-based substrate layer;
b. a silicon oxide barrier coating applied to both sides of the bio-based substrate layer;
c. an ohmic contact layer applied to one side of the silicon oxide barrier coating;
d. a P-type “absorber” layer applied over the ohmic contact layer;
e. an N-type “window” layer applied over the P-type “absorber” layer;
f. an anti-reflection coating applied over the N-type “window” layer; and
g. a transparent conductive coating applied over the anti-reflection coating.
